(19) United States
(12) Patent Application Publication
(10) Pub. No.: US 2023/0076001 A1
(43) Pub. Date: Mar. 9, 2023

(54) HEATSINKS FOR MULTIPLE COMPONENTS

(71) Applicant: HEWLETT-PACKARD DEVELOPMENT COMPANY, L.P., Spring, TX (US)

(72) Inventors: Andrew L. Wiltzius, Fort Collins, CO (US); Robert Lee Crane, Fort Collins, CO (US)

(73) Assignee: HEWLETT-PACKARD DEVELOPMENT COMPANY, L.P., Spring, TX (US)

(21) Appl. No.: 17/794,561

(22) PCT Filed: Feb. 26, 2020
(86) PCT No.: PCT/US2020/019896

§ 371 Date: Jul. 21, 2022

(51) Int. Cl. H05K 7/20; H05K 1/02

(52) U.S. Cl. CPC H05K 7/209; H05K 1/0203

(57) ABSTRACT

An example heat transfer apparatus includes a first heatsink, having a first thermal resistance, to remove heat from a first component, a second heatsink, having a second thermal resistance different from the first thermal resistance, to remove heat from a second component, and a mounting structure supporting the first heatsink to couple the first heatsink to the first component. The second heatsink is supported by the first heatsink to couple the second heatsink to the second component.

### BACKGROUND

An electronic device may include a processor and a voltage regulator (VR) to supply power to the processor. As the processor operates, it produces heat that should be dissipated to avoid damage or reduced capability of the processor. In this regard, a heatsink may be used to remove heat generated by the processor. Depending on the power load supplied by the VR to the processor, the VR may also produce heat that should be dissipated to similarly avoid damage or reduced capability of the VR circuit.

### BRIEF DESCRIPTION OF THE DRAWINGS

Various examples will be described below by referring to the following figures.

FIG. 1A illustrates a heat transfer apparatus according to an example;

FIG. 1B illustrates a heat transfer apparatus according to an example;

FIG. 2A illustrates a heat transfer apparatus including an elastic coupling member according to an example;

FIG. 2B illustrates an elastic coupling member of a heat transfer apparatus according to an example;

FIG. 2C illustrates an elastic coupling member of a heat transfer apparatus according to an example;

FIG. 2D illustrates an elastic coupling member of a heat transfer apparatus according to an example;

FIG. 2E illustrates an elastic coupling member of a heat transfer apparatus according to an example;

FIG. 3 illustrates a heat transfer apparatus according to an example;

FIG. 4 illustrates a multi-tiered heat transfer apparatus according to an example; and

FIG. 5 illustrates a printed circuit board including a heat transfer apparatus according to an example.

### DETAILED DESCRIPTION OF EXAMPLES

Hereinafter, various examples will be described with reference to the drawings. Like reference numerals in the specification and the drawings denote like elements, and thus a redundant description may be omitted.

Various electronic devices, such as a personal computer (PC), may include a processor (e.g., a processing circuit, a microprocessor, a central processing unit (CPU), etc.) and a voltage regulator (VR). The processor may control operations of the electronic device such as by performing arithmetic or logical operations, by decoding and executing instructions stored in a memory, by storing information in the memory, and the like. The VR may provide power to the processor in order that the processor is able to perform its operations. In various examples, the processor and the VR may be provided on a printed circuit board (e.g., a motherboard) and may be provided in proximity to each other.

During operation, the processor may generate heat that should be dissipated to avoid damage or reduced capability of the processor. Similarly, the VR may generate heat that should also be dissipated to avoid damage or reduced capability of the VR. In that regard, the processor may be provided with a heatsink or other cooling apparatus to dissipate the generated heat. Similarly, a heatsink or other cooling apparatus may be provided to dissipate heat generated by the VR.

During design of the electronic device, the power load (e.g., voltage level, current draw, etc.) of the processor may be unknown or may have a wide range. Because the VR provides power to the processor, the load on the VR, which depends on the power load of the processor, may therefore also be unknown. Based on the wide range of power loads that the VR may need to support, it is difficult for a designer to determine the amount of heat that the VR will generate and that will need to be dissipated. In that case, the designer may assume a worst-case loading and heat generation scenario for the VR and design a cooling apparatus based on that assumption. However, if the VR is implemented in a low power environment, the worst-case cooling apparatus may cause an unwarranted expense.

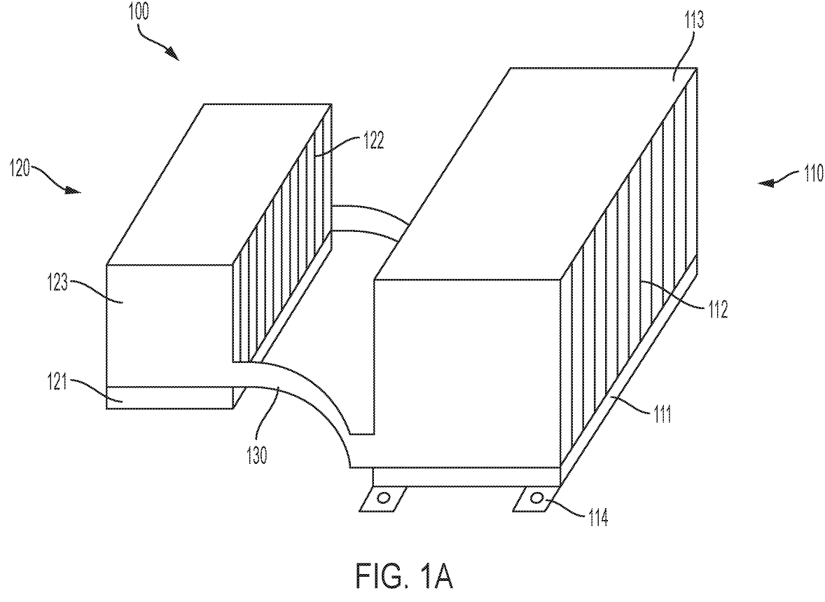

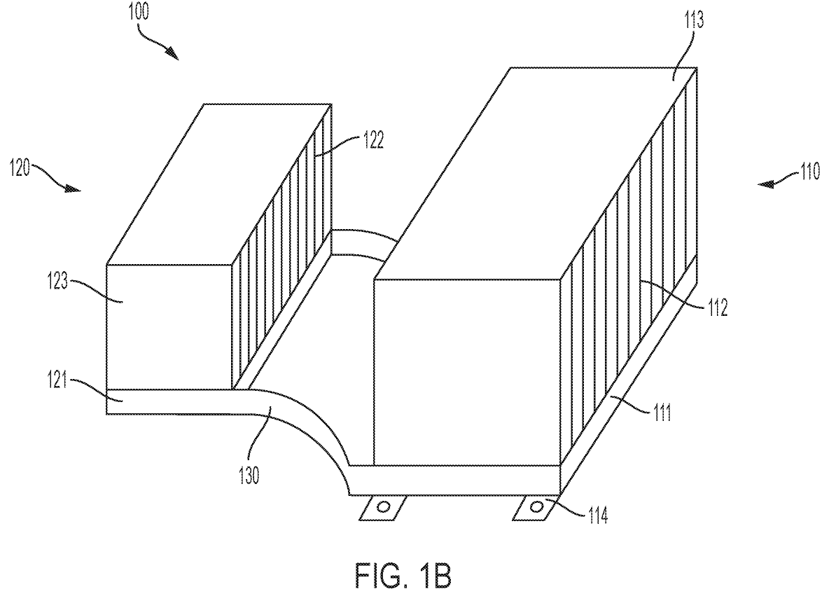

FIG. 1A illustrates a heat transfer apparatus according to an example.

Referring to FIG. 1A, a heat transfer apparatus 100 includes a first heatsink 110, a second heatsink 120, and a coupling support 130.

The first heatsink 110 may include a first base plate 111, first cooling fins 112, a first cover 113, and a mounting structure 114. The first base plate 111 may include a thermally conductive material such as copper, aluminum, a copper alloy, an aluminum alloy, etc. The first base plate 111 may be placed above or on top of a first component so as to contact the first component to dissipate heat generated by the first component. In various examples, the first base plate 111 may contact the first component directly or a thermal interface material may be placed between a bottom of the first base plate 111 and the first component.

The first cooling fins 112 may also include a thermally conductive material such as copper, aluminum, a copper alloy, an aluminum alloy, etc. In an example, the first cooling fins 112 may be formed separately from the first base plate 111 and attached to the first base plate 111 by soldering, brazing, crimping, etc. In another example, the first cooling fins 112 may be formed together with the first base plate 111 by skiving, extrusion, stamping, forging, milling, etc.

The first cover 113 may be provided as a shroud or cover over the first cooling fins 112. The first cover 113 may be provided to reduce dust or other debris from gathering in the first cooling fins 112. The first cover 113 may also be provided for appearance as well as structural support for the first cooling fins 112. In an example, the first cover 113 may be formed separate from the first base plate 111 and coupled to the first base plate 111.

The mounting structure 114 is provided to couple the first heatsink 110 to the first component. In the example of FIG. 1A, the mounting structure 114 is provided as a tab having a hole formed therein. The hole formed in the mounting structure 114 may receive a pin, a screw, a threaded post, etc. to couple the first heatsink 110 to a hole formed in the first component, to a hole formed in a socket in which the first component is located, or to a hole formed in a circuit board on which the first component is mounted. As an example, the mounting structure 114 may include a tab having a hole formed therein that receives a threaded post included with a socket frame in which the first component is mounted. Upon receiving the threaded post through the hole, a nut or similar fastener may be attached to the threaded post to secure the mounting structure 114 to the socket frame and thus secure the first heatsink 110 to the first component.

The placement and design of the mounting structure 114 may be selected in consideration of a mounting structure of the first component. For example, a location of the mounting structure 114, a size of the hole of the mounting structure 114, etc. may be selected in consideration of a mounting structure of the first component. In various examples, the mounting structure 114 may include a post, a threaded shaft, a leg, etc. in order to couple the first heatsink 110 to the first component. In another example, the mounting structure 114 may couple to an enclosure in which the first component is located. As an example, if the first component includes a processor mounted on a motherboard for use in a personal computer (PC), the mounting structure 114 may couple with a chassis of the PC in which the motherboard is located. In various examples, the mounting structure 114 may be formed as an extension of the first base plate 111, as an extension of the first cover 113, or as a separate component that is coupled to the first heatsink 110.

The second heatsink 120 may include a second base plate 121, second cooling fins 122, and a second cover 123. The second base plate 121 may include a thermally conductive material such as copper, aluminum, a copper alloy, an aluminum alloy, etc. The second base plate 121 may contact a second component, such as a voltage regulator, to dissipate heat generated by the second component. In various examples, the second base plate 121 may contact the second component directly or a thermal interface material may be placed between a bottom of the second base plate 121 and the second component.

The second cooling fins 122 may also include a thermally conductive material such as copper, aluminum, a copper alloy, an aluminum alloy, etc. In an example, the second cooling fins 122 may be formed separately from the second base plate 121 and attached to the second base plate 121 by soldering, brazing, crimping, etc. In another example, the second cooling fins 122 may be formed together with the second base plate 121 by skiving, extrusion, stamping, forging, milling, etc.

The second cover 123 may be provided as a shroud or cover over the second cooling fins 122. The second cover 123 may be provided to reduce dust or other debris from gathering in the second cooling fins 122. The second cover 123 may also be provided for appearance as well as structural support for the second cooling fins 122. The second cover 123 may be formed separate from the second base plate 121 and coupled to the second base plate 121.

The coupling support 130 is provided between the first heatsink 110 and the second heatsink 120. The coupling support 130 may allow the first heatsink 110 to support the second heatsink 120 in a manner such that the second heatsink 120 is coupled to the second component. The dimensions of the coupling support 130 may be determined by the logistics of the first component, the second component, and a circuit board upon which the first component and the second component are mounted. For example, a distance between the first and second component, a height difference between the first component and the second component, a size (e.g., length, width, etc.) of the first component and the second component, etc. may influence the dimensions of the coupling support 130.

The coupling support 130 provided between the first heatsink 110 and the second heatsink 120 allows a user (e.g., a designer, a manufacturer, an equipment owner, etc.) to design the first heatsink 110 and the second heatsink 120 based on the operating parameters of the circuit in which the first heatsink 110 and the second heatsink 120 will be used. For example, in a case in which the first component is a processor and the second component is a voltage regulator that supplies power to the processor, the user may determine the operating parameters of the processor and the power load of the VR based on the operating parameters of the processor. Based on the operating parameters of the processor, the user may determine a heat load produced by the processor and select the first heatsink 110 to have a first thermal resistance to address the expected heat load. Similarly, based on the power load of the VR, which is based on the operating parameters of the processor, the user is able to determine a heat load produced by the VR and select a second heatsink 120 to have a second thermal resistance to address the expected power load.

If the user replaces the processor with a second processor having operating parameters that create a greater heat load than that of the processor, the first heatsink 110 may be replaced to address the greater heat load. However, the operating parameters of the second processor that create the greater heat load than that of the processor may include a higher power demand by the second processor than that of the processor. Because power is supplied from the VR, the higher power demand of the second processor may cause more power and thus additional heat to be produced by the VR such that the second heatsink 120 may be replaced as well as the first heatsink 110. The coupling support 130 allows the user to select a heat transfer apparatus that provides heat dissipation for both the first component (e.g., processor) and the second component (e.g., VR). That is, a cooling capacity (e.g., thermal resistance) of the second heatsink 120 may correspond to a power load of the first component (e.g., processor). Thus, the user is able to avoid assuming a worst-case scenario when designing a heatsink for the second component and thus is able to save costs. Furthermore, the coupling support 130 and the mounting structure 114 allow the user to replace both the first heatsink 110 and the second heatsink 120 simultaneously using a single mounting structure. Thus, according to an example, a downtime needed to replace the first heatsink 110 and the second heatsink 120 is reduced as compared to a downtime needed to replace both a mounting structure of the first heatsink 110 and a separate mounting structure of the second heatsink 120. Also, the coupling support 130 and the mounting structure 114 eliminate the need for a receiving mounting structure (e.g., circuit board mounting holes) for the second heatsink 120. Thus, an area on a circuit board that may otherwise be used to mount the second heatsink 120 can instead be used for wiring or placement of other components, for example.

In the example of FIG. 1A, the coupling support 130 is provided as an extension between the first cover 113 and the second cover 123. The coupling support 130 may be integrally formed with the first cover 113 and the second cover 123 or may be separately formed and coupled to the first cover 113 and the second cover 123.

FIG. 1B illustrates a heat transfer apparatus according to an example.

In the following description, differences between the heat transfer apparatus 100 of FIG. 1B and the heat transfer apparatus 100 of FIG. 1A are mainly described. Elements that perform the same functions as those described with reference to FIG. 1A are denoted by the same reference numerals, and redundant descriptions thereof are omitted.

Referring to FIG. 1B, the heat transfer apparatus 100 includes the first heatsink 110, the second heatsink 120, and the coupling support 130.

The coupling support 130 is provided between the first heatsink 110 and the second heatsink 120 to allow the first heatsink 110 to support the second heatsink 120 in a manner such that the second heatsink 120 is coupled to a second component. The dimensions of the coupling support 130 may be determined by the logistics of a first component, the second component, and a circuit board upon which the first component and the second component are mounted. For example, a distance between the first and second component, a height difference between the first component and the second component, a size (e.g., length, width, etc.) of the first component and the second component, etc. may influence the dimensions of the coupling support 130.

In the example of FIG. 1B, the coupling support 130 is provided as an extension between the first base plate 111 and the second base plate 121. The coupling support 130 may be integrally formed with the first base plate 111 and the second base plate 121 or may be separately formed and coupled to the first base plate 111 and the second base plate 121. In other examples, the coupling support 130 may be provided as an extension of the first base plate 111 to the second cover 123 or as an extension from the first cover 113 to the second base plate 121.

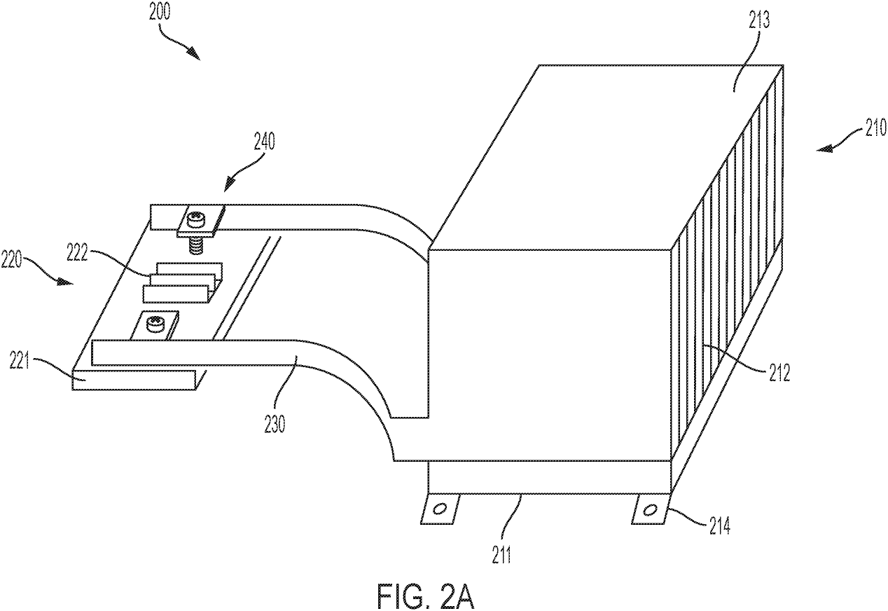

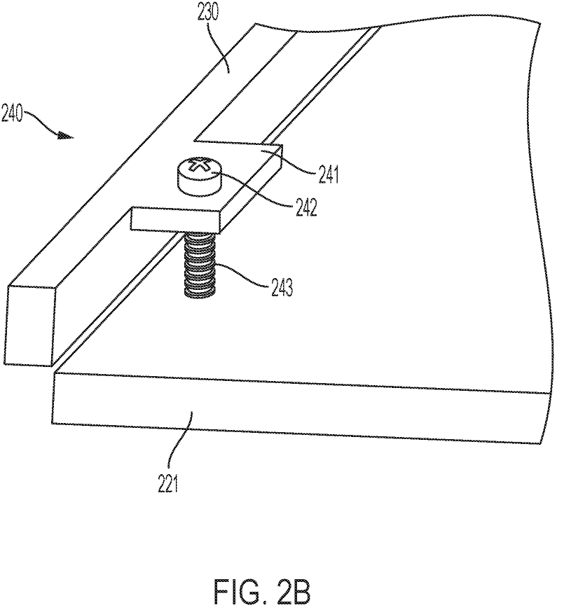

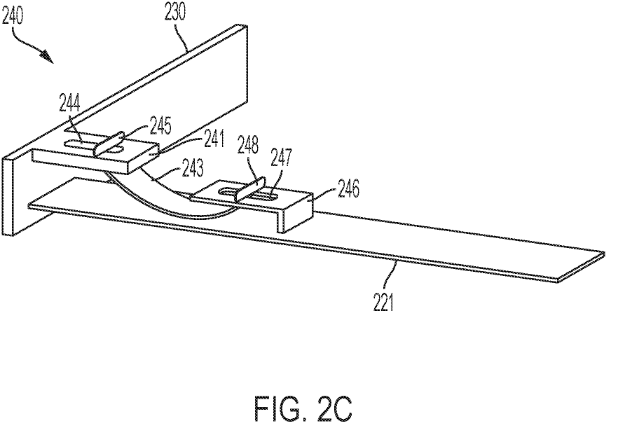

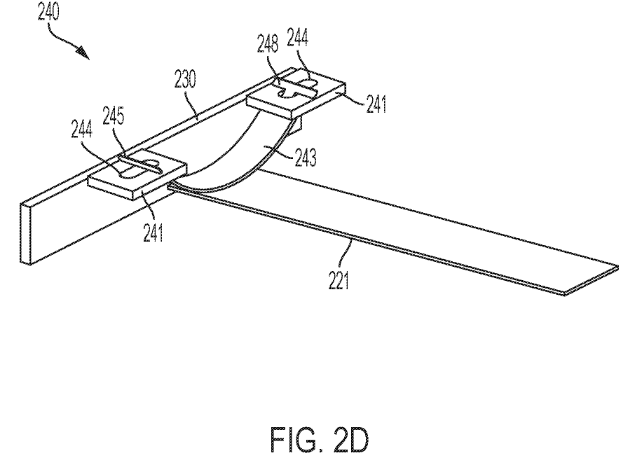

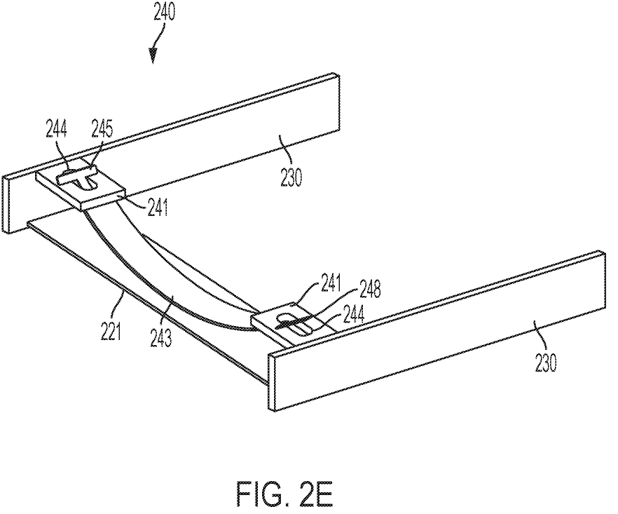

FIG. 2A illustrates a heat transfer apparatus including an elastic coupling member according to an example.

Referring to FIG. 2A, a heat transfer apparatus 200 includes a first heatsink 210, a second heatsink 220, and a coupling support 230. The heat transfer apparatus 200 is similar to the heat transfer apparatus 100 described above. For example, elements 211, 212, 213, 214, 221, 222, and 230 are similar to elements 111, 112, 113, 114, 121, 122, and 130 described above and redundant descriptions thereof are omitted for conciseness. Although not illustrated, a second cover for the second heatsink 220, similar to the second cover 123 illustrated in FIG. 1A or FIG. 1B, may also be included. The second cover is not illustrated in FIG. 2A to avoid obscuring the elements that are described.

In the example of FIG. 2A, the second heatsink 220 includes an elastic coupling member 240. The elastic coupling member 240 may reduce a mounting force from the second heatsink 220 on a second component. For example, the first heatsink 210 including the mounting structure 214 may be designed to couple with a first component using a first mounting force. As an example, if the first heatsink 210 is to be coupled to a first component that is mounted to a circuit board using a mounting socket, the mounting force applied by the first heatsink 210 may be large. If the second component is not mounted to the circuit board with a mounting socket, the mounting force to be applied by the second heatsink 220 to the second component may not be as large as the mounting force on the first component. To address the differences in acceptable mounting forces, the parameters of the coupling support 230 (e.g., height, length, width, material, etc.) may be selected to reduce a mounting force (e.g., a downward pressure) on the second component. However, it may be difficult to ensure a sufficiently low mounting force by the second heatsink 220 on the second component based on the parameters of the coupling support 230.

The elastic coupling member 240 may be integrated with the coupling support 230 or formed separately from the coupling support 230 and attached to the coupling support 230.

FIG. 2B illustrates an elastic coupling member of a heat transfer apparatus according to an example.

Referring to FIG. 2B, the elastic coupling member 240 includes a tab or shoulder 241 extending from the coupling support 230. The tab 241 includes an opening (e.g., through hole) formed therein through which a pin 242 is inserted. A first end of the pin 242 includes a flanged head having a size (e.g., diameter) greater than that of the opening formed in the tab 241. A second end of the pin 242, opposite to the first end, is coupled to the second base plate 221. In an example, the second end of the pin 242 may be adhered to the second base plate 221 using an adhesive (e.g., a glue, a tape, etc.). In other examples, the second base plate 221 may include an opening formed therein, corresponding to a location of the opening formed in the tab 241, through which the second end of the pin 242 may extend. In that case, the second end of the pin 242 may protrude from a bottom surface of the second base plate 221 and include a flanged head having a size (e.g., diameter) greater than that of the opening formed in the second base plate 221. In another example, the pin 242 may be threaded at the second end to couple with the second base plate 221. In that example, the second base plate 221 may include an opening that is similarly threaded to receive the second end of the pin 242. The through hole provided in the tab 241 is not threaded to ensure the pin 242 is able to move therein.

The elastic coupling member 240 includes an elastic member 243. In the example of FIG. 2B, the elastic member 243 is illustrated as a coil spring. The elastic member 243 provides a downward force on the second base plate 221 to provide a mounting force on the second component. In the example in which the elastic member 243 is provided as a coil spring, a spring constant may be selected to provide a desired mounting force. In an example in which the second end of the pin 242 is threaded, the amount of engagement of the pin 242 with the threaded mounting hole of the second base plate 221 may allow a user to shorten the available travel distance of the spring and thus further control the desired mounting force.

FIGS. 2C, 2D, and 2E illustrate an elastic coupling member of a heat transfer apparatus according to various examples.

Referring to FIG. 2C, the elastic coupling member 240 includes a tab or shoulder 241 extending from the coupling support 230. The tab 241 includes a slot 244 as an opening formed therein. In the example of FIG. 2C, the elastic member 243 is illustrated as a leaf spring. The elastic member 243 provides a downward force on the second base plate 221 to provide a desired mounting force on the second component. As an example, the elastic member 243 may reduce a mounting force on the second component as compared to a mounting force applied to the first component. In that regard, the elastic member 243 may be formed of a material selected based on its elasticity and may be modified in shape (e.g., length, width, thickness) to achieve a desired mounting pressure on the second component.

The elastic member 243 may include a first coupling tab 245 located at a first end of the elastic member 243. The first coupling tab 245 may be received through the slot 244. A size of the slot 244 may allow the first coupling tab 245 to be received therein at a first orientation and twisted to a second orientation (e.g., 90° relative to the first orientation) such that the first coupling tab 245 is unable to pull through the slot 244. A second end of the elastic member 243, opposite to the first end of the elastic member 243, may include a second coupling tab 248. In the example of FIG. 2C, the second base plate 221 may include a tab 246 including a slot 247 formed therein. In that case, the second coupling tab 248 may be received through the slot 247 formed in the tab 246. A size of the slot 247 may allow the second coupling tab 248 to be received therein at a first orientation and twisted to a second orientation (e.g., 90° relative to the first orientation) such that the second coupling tab 248 is unable to pull through the slot 247.

In the example of FIG. 2C, one coupling support 230 and one elastic coupling member 240 having one elastic member 243 are illustrated. However, in other examples, an additional coupling support 230 and an additional elastic coupling member 240 including an elastic member 243 may be provided. In that case, the second base plate 221 may include an additional tab 246 to receive the additional elastic member 243.

Referring to FIG. 2D, the elastic coupling member 240 includes tabs or shoulders 241 extending from the coupling support 230. Each tab 241 includes a slot 244 as an opening formed therein. In the example of FIG. 2D, the elastic member 243 is illustrated as a leaf spring to provide a desired mounting force on the second component through the second base plate 221.

The elastic member 243 may include the first coupling tab 245 located at the first end of the elastic member 243 and the second coupling tab 248 located at the second end of the elastic member 243. Each of the first coupling tab 245 and the second coupling tab 248 may be respectively received through the slots 244 of the tabs 241. A size of each slot 244 may respectively allow the first coupling tab 245 and the second coupling tab 248 to be received therein at a first orientation and twisted to a second orientation (e.g., 90° relative to the first orientation) such that the first coupling tab 245 and the second coupling tab 248 are unable to pull through the respective slots 244.

In the example of FIG. 2D, the elastic member 243 may couple to the second base plate 221 using an adhesive such as glue, tape, etc. In that case, the elastic member 243 may be prevented from separating from the second base plate 221 to improve the ease of installation of the second base plate 221 above the second component. In the example of FIG. 2D, one coupling support 230 and one elastic coupling member 240 having one elastic member 243 are illustrated. However, in other examples, an additional coupling support 230 and an additional elastic coupling member 240 including an elastic member 243 may be provided.

Referring to FIG. 2E, the elastic coupling member 240 includes the elastic member 243 that is provided as a leaf spring to span between coupling supports 230 and provide a mounting force on the second component through the second base plate 221. In the example of FIG. 2E, the elastic coupling member 240 includes the first tab or shoulder 241 extending from each coupling support 230. Each tab 241 includes the first slot 244 as an opening formed therein.

The elastic member 243 may include the first coupling tab 245 located at the first end of the elastic member 243 and the second coupling tab 248 formed at the second end of the elastic member 243, opposite to the first end of the elastic member 243. The first coupling tab 245 and the second coupling tab 248 may be respectively received through slots 244 formed in the tabs 241 that are located on the coupling supports 230. A size of each slot 244 may allow the first coupling tab 245 and the second coupling tab 248 to be received therein at a first orientation and twisted to a second orientation (e.g., 90° relative to the first orientation) such that the first coupling tab 245 and the second coupling tab 248 are unable to pull through the respective slots 244.

In the example of FIG. 2E, the elastic member 243 may couple to the second base plate 221 using an adhesive such as glue, tape, etc. In that case, the elastic member 243 may be prevented from separating from the second base plate 221 to improve the ease of installation of the second base plate 221 above the second component.

In other various examples, the elastic member 243 may include a pin rather than the first coupling tab 245 and/or the second coupling tab 248. In that case, the pin(s) may be received through the slot 244 and/or 247. Similarly, the slot 247 may be formed in the second base plate 221 such that the tab 246 may not be provided. Further, the first and second ends of the elastic member 243 may be respectively coupled to the tabs 241 and/or 246 using an adhesive such that the slots 244 and/or 247 may not be provided.

In another example, the elastic member 243 may be an elastic adhesive tape. In the case in which the elastic member 243 is an elastic adhesive tape, the pin 242 may not be included as the elastic adhesive tape structurally couples the tab 241 with the second base plate 221. In the examples of using the pin 242 and an elastic member 243 including a coil spring, using slot 244 and an elastic member 243 including a leaf spring, or of using an elastic adhesive tape as the elastic member 243, a mounting force of the second heatsink 220 on the second component may be reduced as compared to the mounting force of the first heatsink 210 on the first component.

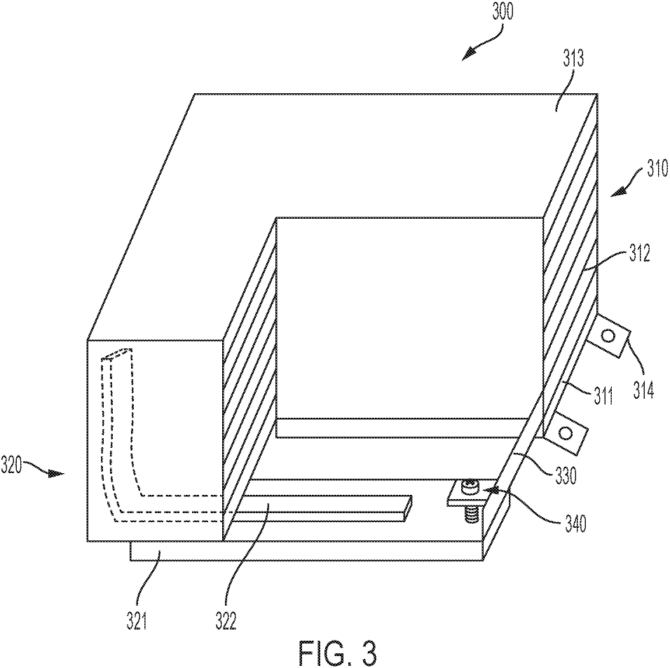

FIG. 3 illustrates a heat transfer apparatus according to an example.

Referring to FIG. 3, a heat transfer apparatus 300 includes a first heatsink 310, a second heatsink 320, and a coupling support 330. The heat transfer apparatus 300 is similar to the heat transfer apparatus 100 described above. For example, elements 311, 314, 321, and 330are similar to elements 111, 114, 121, and 130 described above and redundant descriptions thereof may be omitted for conciseness.

In the example of FIG. 3, the second heatsink 320 includes a heat pipe 322. The heat pipe 322 may be formed of a thermally conductive material, such as copper, aluminum, a copper alloy, an aluminum alloy, etc. and include an internal structure in which a liquid is provided. The heat pipe 322 may transfer heat through capillary action and phase change of the liquid. In that regard, an internal structure of the heat pipe 322 may include a wick or a geometrical feature (e.g., grooves) to provide the capillary action. In an example, the liquid may be water and may be provided within the heat pipe 322 at a reduced pressure. The heat pipe 322 may be formed separate from the second base plate 321 and coupled to the second base plate 321, or may be formed together with the second base plate 321.

In the example of FIG. 3, first cooling fins 312 and a first cover 313 of the first heatsink 310 extend in an “L” shape to receive the heat pipe 322. A thermal coupling may be formed between the heat pipe 322 and the first cooling fins 312 such that heat received and conducted by the heat pipe 322 may be dissipated by the first cooling fins 312. In another example, second cooling fins separate from the first cooling fins 312, may be provided with the second heatsink 320 to receive the heat pipe 322 and dissipate heat received from the heat pipe 322.

As illustrated in FIG. 3, the coupling support 330 may include an elastic coupling member 340. Further, although one coupling support 330 is shown in FIG. 3, this is for convenience and a plurality of coupling supports 330 including elastic coupling members 340 may be included.

In other examples, the second base plate 321 may not be included. In that case, the heat pipe 322 may contact the second component directly, or through a thermal interface material. In another example, the coupling support 330 may not be included. In that case, the thermal coupling between the heat pipe 322 and the first cooling fins 312 may structurally support the heat pipe 322 to couple with the second component. Further in that case, the heat pipe 322 may provide an elasticity that reduces a mounting force on the second component. As an example, the material or dimensions of the heat pipe 322 may be selected to provide a desired elasticity of the heat pipe 322 so as to reduce a mounting force on the second component.

In other examples, a vapor chamber, a three-dimensional (3D) vapor chamber, a liquid cooling cold plate, etc. may be selected for use with the second heatsink 320 rather than the heat pipe 322.

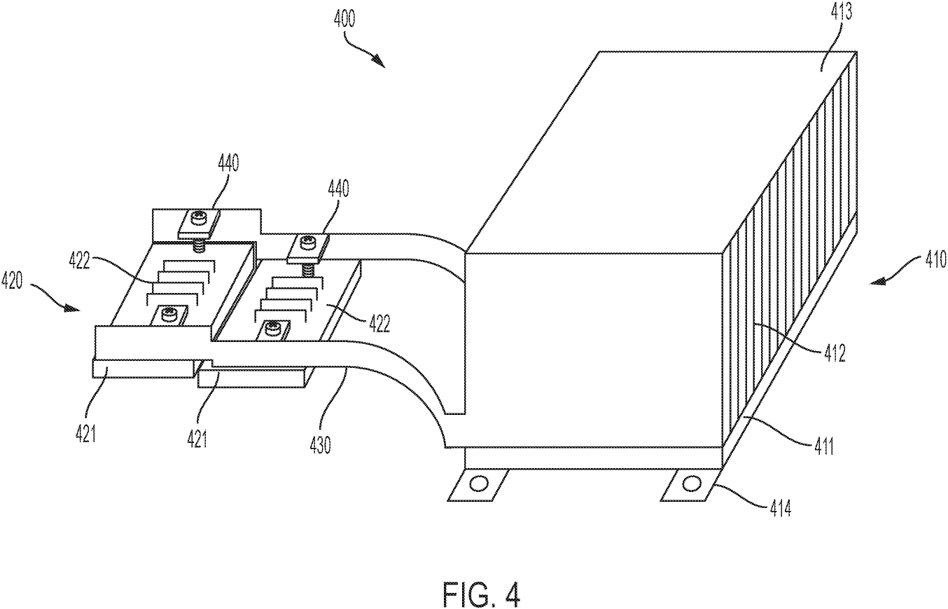

FIG. 4 illustrates a multi-tiered heat transfer apparatus according to an example.

Referring to FIG. 4, a heat transfer apparatus 400 includes a first heatsink 410, a second heatsink 420, and a coupling support 430. The heat transfer apparatus 400 is similar to the heat transfer apparatus 100 described above. For example, elements 411, 412, 413, and 414 are similar to elements 111, 112, 113, and 114 described above and redundant descriptions thereof may be omitted for conciseness.

In the example of FIG. 4, the second heatsink 420 is provided as a multi-tiered heatsink. For example, if the second component included a multi-tiered arrangement, or if it is desired to provide cooling for a third component, the second heatsink 420 may be multi-tiered.

As illustrated in FIG. 4, the second heatsink 420 may include second base plates 421 arranged at different heights relative to the first base plate 411. In other examples, dimensions of the second base plates 421 may be selected based on the arrangement of the second component. For example, a property (e.g., length, width, height, material) may be different between the second base plates 421.

The second heatsink 420 may also include second cooling fins 422 to further dissipate heat respectively received from the second base plates 421. Although not illustrated, the second heatsink 420 may further include second covers.

The coupling support 430 may couple the second heatsink 420 to the first heatsink 410. In the example of FIG. 4, the coupling support 430 has a notched structure corresponding to a height difference of the second base plates 421. The coupling support 430 may also include elastic coupling members 440. The elastic coupling members 440 may reduce a mounting force on each component of the multi-tiered second component in relation to the mounting force applied by the first heatsink 410 on the first component. Also, the elastic coupling members 440 may provide different mounting forces on each tier of the second component based on selection of an elastic member (e.g., 243) or an adjustment of a threaded pin (e.g., 242).

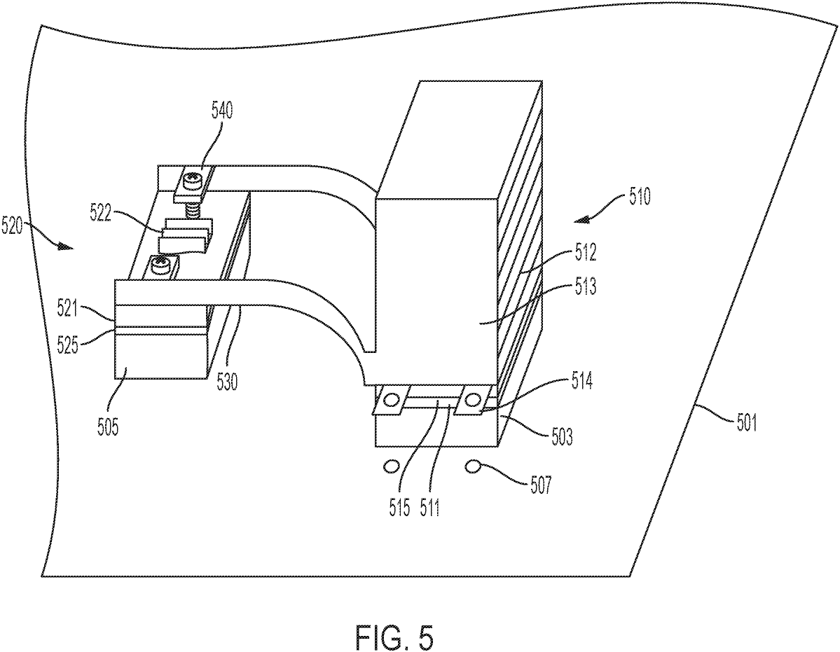

FIG. 5 illustrates a printed circuit board including a heat transfer apparatus according to an example.

Referring to FIG. 5, a printed circuit board (PCB) 501 may have mounted thereon a processor 503 and a VR 505. The processor 503 may include a processing circuit, a microprocessor, a CPU, etc. The processor 503 may be mounted to the PCB 501 using a through-hole package, a surface mount, a chip carrier, a pin-grid array, a flat package, a ball grid array, etc. Further, the PCB 501 may include a socket for coupling the processor 503 to the PCB 501.

The VR 505 may include circuitry for regulating a received input voltage and for outputting an operating voltage to the processor 503. The VR 505 may be implemented as an integrated circuit, as individual electronic components, or a combination of both. The VR 505 may be mounted to the PCB 501 using a through-hole package, a surface mount, a chip carrier, a pin-grid array, a flat package, a ball grid array, etc.

A heat transfer apparatus is provided to dissipate heat from the processor 503 and the VR 505. In the example of FIG. 5, the heat transfer apparatus includes a first heatsink 510, a second heatsink 520, and a coupling support 530.

The first heatsink 510 may include a first base plate 511, first cooling fins 512, a first cover 513, and a mounting structure 514. The second heatsink 520 may include a second base plate 521, second cooling fins 522, and a second cover (not shown). The elements 511, 512, 513, 514, 521, and 522 are similar to elements 111, 112, 113, 114, 121, and 122 described above and redundant descriptions thereof may be omitted for conciseness.

The first base plate 511 is to remove heat generated from the processor 503 and the first cooling fins 512 are to remove heat received from the first base plate 511. Although not shown, the PCB 501 may further include one or more fans or other structure to force air through the first cooling fins 512. In the example of FIG. 5, a thermal interface material 515 is provided between a bottom surface of the first base plate 511 and a top surface of the processor 503. However, in other examples, the first base plate 511 may directly contact the top surface of the processor 503.

In selecting the first heatsink 510, a user may determine a heat load of the processor 503 and select the first heatsink 510 to have a cooling capacity (e.g., a first thermal resistance) to dissipate the heat load of the processor 503.

The PCB 501 includes a mounting receiver 507 that corresponds to the mounting structure 514. As an example, the mounting structure 514 may include a tab having an opening formed therein such that a screw or other fastener (not shown) may couple the mounting structure 514 to the mounting receiver 507. In that case, the first heatsink 510 is coupled to the processor 501 with a first mounting force.

The second heatsink 520 includes the second base plate 521 and the second cooling fins 522. The second base plate 521 is to remove heat generated by the VR 505 and the second cooling fins 522 are to remove heat received from the second base plate 521. If included, the one or more fans may also force air through the second cooling fins 522. In the example of FIG. 5, a thermal interface material 525 is provided between a bottom surface of the second base plate 521 and a top surface of the VR 505. However, in other examples, the second base plate 521 may directly contact the top surface of the VR 505.

In selecting the second heatsink 520, a user may determine a heat load of the VR 505 and select the second heatsink 520 to have a cooling capacity (e.g., a second thermal resistance) to dissipate the heat load of the VR 505. Because the heat load of the VR 505 may correspond to the power load of the processor 503, the second heatsink 520 may be selected with the first heatsink 510. In that case, costs for providing a second heatsink 520 assuming a worst-case heat load can be avoided, for example.

The coupling support 530 couples the first heatsink 510 to support the second heatsink 520 in a manner such that the second heatsink 520 is coupled to the VR 505. The dimensions of the coupling support 530 may be determined based on a separation distance between the processor 503 and the VR 505, a height difference between the processor 503 and the VR 505, etc.

The coupling support 530 may include an elastic coupling member 540. The elastic coupling member 540 may reduce a mounting force applied to the VR 505 as compared to the first mounting force applied to the processor 503. In that regard, the first mounting force applied to the processor 503 may correspond to a force applied between the mounting structure 514 and the mounting receiver 507. However, because the first mounting force applied to the processor 503 may exceed an acceptable mounting force applicable to the VR 505, the elastic coupling member 540 is provided to reduce the mounting force on the VR 505.

By coupling the first heatsink 510 and the second heatsink 520 with the coupling support 530, a dedicated mounting structure for the second heatsink 520 is not provided. For example, a mounting receiver, similar to the mounting receiver 507 used to mount the first heatsink 510, is not provided to mount the second heatsink 520. In that case, the PCB 501 may increase an amount of available area for wiring, other components, etc.

If it is desired to replace the processor 503 with a second processor having a greater heat load and a greater power load than the processor 503, the first heatsink 510 may be replaced. In that case, because the second processor has a greater power load, the load on the VR 505 may increase such that the heat generated by the VR 505 is also increased and the second heatsink 520 may need to be replaced. Using a heat transfer apparatus having a coupling support such as coupling support 530, a user is able to replace both the first heatsink 510 and the second heatsink 520 at the same time. In that case, the user is able to replace both the first heatsink 510 and the second heatsink 520 by manipulating the mounting structure 514 as opposed to manipulating a mounting structure for the first heatsink 510 and a separate mounting structure for the second heatsink 520, which reduces the time to process the replacement. Further, the cost of using a worst-case heatsink for the VR 505 is reduced as the user is able to increase the cooling capacity (e.g., second thermal resistance) of the second heatsink 520 when desired.

It should be understood that examples described herein should be considered in a descriptive sense and not for purposes of limitation. Descriptions of features or aspects within each example should typically be considered as available for other similar features or aspects in other examples. While one or more examples have been described with reference to the figures, it will be understood by those of ordinary skill in the art that various changes in form and details may be made therein without departing from the spirit and scope as defined by the following claims.

What is claimed is:

1. A heat transfer apparatus comprising:
a first heatsink, having a first thermal resistance, to remove heat from a first component;
a second heatsink, having a second thermal resistance different from the first thermal resistance, to remove heat from a second component; and
a mounting structure supporting the first heatsink to couple the first heatsink to the first component,
wherein the second heatsink is supported by the first heatsink to couple the second heatsink to the second component.

2. The heat transfer apparatus of claim 1,
wherein the first heatsink includes a first cover, and
wherein the second heatsink is supported by an extension of the first cover.

3. The heat transfer apparatus of claim 2, further comprising an elastic member to reduce a mounting force of the second heatsink.

4. The heat transfer apparatus of claim 2, further comprising a thermal interface to couple the second heatsink to the second component.

5. The heat transfer apparatus of claim 1,
wherein the first heatsink includes a first base plate,
wherein the second heatsink includes a second base plate, and
wherein the second heatsink is supported by an extension of the first base plate to the second base plate.

6. The heat transfer apparatus of claim 5, further comprising an elastic member to reduce a mounting force of the second heatsink.

7. The heat transfer apparatus of claim 6, further comprising a thermal interface to couple the second heatsink to the second component.

8. The heat transfer apparatus of claim 5,
wherein the second base plate includes a multi-tiered base plate, and
wherein the second heatsink includes a multi-tiered heatsink.

9. A heat transfer apparatus comprising:
a first heatsink to remove heat from a first component;
a mounting structure supporting the first heatsink to couple the first heatsink to the first component; and
a second heatsink to remove heat from a second component,
wherein the second heatsink is supported by the first heatsink to couple the second heatsink to the second component.

10. The heat transfer apparatus of claim 9,
wherein the first heatsink includes a first cover, and
wherein the second heatsink is supported by an extension of the first cover.

11. The heat transfer apparatus of claim 10, wherein the second heatsink includes a heat pipe and a thermal interface, the thermal interface to couple the heat pipe to the second component.

12. The heat transfer apparatus of claim 11, wherein the heat pipe is coupled to the first heatsink.

13. The heat transfer apparatus of claim 11, wherein the heat pipe is coupled to the second heatsink.

14. The heat transfer apparatus of claim 11, wherein the heat pipe is formed to have an elasticity to reduce a mounting force on the second component.

15. A circuit motherboard comprising:
a first component;
a first heatsink including a first cover, the first heatsink being coupled to the first component;
a second component; and
a second heatsink supported by the first heatsink to couple the second heatsink to the second component,
wherein a thermal resistance of the second heatsink corresponds to a power load of the first component, and
wherein the first component includes a processor and the second component includes a voltage regulator.
